(19) United States
(12) Patent Application Publication
(10) Pub. No.: US 2012/0007140 A1
(43) Pub. Date: Jan. 12, 2012

(54) ESD self protecting NLDMOS device and NLDMOS array

(75) Inventor: Vladislav Vashchenko, Palo Alto, CA (US)

(73) Assignee: National Semiconductor Corporation

(21) Appl. No.: 12/804,070

(22) Filed: Jul. 12, 2010

(51) Int. Cl. H01L 27/06

(52) U.S. Cl. 257/140; 257/E27.017; 257/335

(57) ABSTRACT

In an NLDMOS array, the source fingers are terminated by p+ Pbody diffusions or Pbody diffusions. The drain-source spacing is reduced by arranging p+ Pbody regions for contacting the Pbody, in line with n+ source regions to define source fingers with interdigitated p+ Pbody regions.

### FIELD OF THE INVENTION

The present invention deals with high voltage devices that can withstand ESD events. In particular, it deals with self protection of power NLDMOS devices, especially NLDMOS arrays.

### BACKGROUND OF THE INVENTION

The present invention deals with NLDMOS devices and arrays of such devices for high power switching applications. For purposes of this application the term NLDMOS will include BCD NLDMOS (Bipolar CMOS DMOS N-laterally doped Metal Oxide Semiconductor), NLDMOS-SCR (NLDMOS-Silicon Controlled Rectifier) and two stage NLDMOS-SCR ESD (NLDMOS-SCR Electrostatic Discharge) devices.

The present invention deals specifically with methods of improving the self-protection capability of such devices and arrays to ESD events. Self protection is a function of the critical avalanche current per micron width and the on-state parameters and gate coupling, which depend on the doping profiles. Even large arrays can have very low critical avalanche current. For example a 100 volt power array with total gate width of 60 mm has been found to suffer from local burnout at a 2 kV HBM pulse. This corresponds to an average current density of only 22 micro Amps per micron width if one assumes a uniform current distribution across the array.

NLDMOS and DMOS devices are typically intended to be used in normal mode (non-snapback mode) and will be destroyed if they go into snapback. Even high voltage NLDMOS and DMOS devices will only survive if the voltage they are handling does not exceed the capabilities of the device. While these devices typically are meant not to go into snapback, local overstresses due to current crowding can cause these devices to go into snapback, thereby damaging the device. Thus, in the case of an ESD event, unless the device is made extremely large, the device is pushed past its capabilities and goes into snapback, causing irreversible breakdown. Typically the margin is rather small before the devices go into snapback. This problem is exacerbated by the fact that the snapback voltage is dependent on gate bias and in practice high-voltage devices used for voltage regulation to provide a low voltage to internal circuits are often not directly connected to the power pad and ground. Thus they fail to provide local clamping of the high voltage pad and ground.

A typical NLDMOS, more correctly referred to as a drain extended MOS (DeMOS) is shown in cross-section in FIG. 1, which includes an n-epitaxial layer 100 in which an n-drift region 102 is formed. In the case of a BiCMOS process an n-buried layer (NBL) 103 may also be formed in the n-epi 100. An n+ drain 104 is formed in the n-drift region 102, and an n+ source 106 is formed in a p-body 108 in the n-epi 100. A polysilicon gate 110 is formed on top of the p-body 108 and n-drift 102, the gate 110 being isolated from the n-well 102 by an isolation oxide 112. As shown in FIG. 1, the drain 104 includes a drain contact 114, the source 106 includes a source contact 116, and the gate 110 includes a gate contact 120. The NLDMOS further includes a p+ P-body region 122 in the p-body 108 for contacting the p-body 108 through the p-body contact 124.

FIG. 2 shows another prior art device in cross-section, namely an NLDMOS-SCR, which differs from the NLDMOS device described above in that it is capable of operating in snapback mode. This device includes an n-epitaxial layer 200 grown on a p-substrate 201. An n-well or n-drift 202 is formed in the n-epi 200. In the case of a BiCMOS process an n-buried layer (NBL) 203 may also be formed in the n-epi 200. In the n-epitaxial layer 200, an n+ drain 204 is formed, and an n+ source 206 is formed in a p-body 208 in the n-epi 200. A polysilicon gate 210 is formed on top of the n-drift 202 and p-body 208, the gate 210 being isolated from the n-drift 202 by an isolation oxide 212. As shown in FIG. 2, the drain 204 includes a drain contact 214, the source includes a source contact 216, and the gate 210 includes a gate contact 220. The NLDMOS-SCR further includes a p+ P-body region 222 in the p-body 208 for the p-body contact 224. Unlike the NLDMOS of FIG. 1, the NLDMOS-SCR further includes a p-emitter region 226 formed under the drain contact.

### SUMMARY OF THE INVENTION

According to the invention, there is provided an NLDMOS device that includes an n+ drain region, at least one n+ source region forming a source finger that defines a longitudinal axis, and a P body with at least one p+ P body diffusion region, wherein the end of the source finger is defined by a P body diffusion. The at least one p+ P body diffusion region may be arranged substantially along the longitudinal axis of the at least one n+ source region to define a source finger with at least one interdigitated p+ P body diffusion region. A p+ P body diffusion region may be included at the end of the source finger. The NLDMOS may further include an n-well or n-sinker region extending underneath the n+ drain region.

Further, according to the invention, there is provided a method of increasing the critical avalanche current of an NLDMOS device that includes an n+ drain region, at least one n+ source region defining a source finger, and a P body with at least one p+ P body diffusion region, the method comprising providing at least one of, a p-type end region to the source finger, and an interdigitated p+ P body implant into the source finger. The p-type end region may comprise a P body implant or a p+ P body implant. The method may further comprise providing a drain side n-well or n-sinker implant.

Still further, according to the invention, there is provided a NLDMOS array comprising multiple NLDMOS devices, each device including an n+ drain region, at least one n+ source region defining a source finger, and a P body with at least one p+ P body diffusion region, wherein the source fingers define an end formed by a P body implant or a p+ P body implant. Adjacent NLDMOS devices in the array preferably share a source finger. The source fingers may each have one or more interdigitated p+ P body diffusions wherein the n+ source regions and p+ P body diffusions lie in the same plane.

### BRIEF DESCRIPTION OF THE DRAWINGS

FIG. 1 shows a cross section through a prior art NLDMOS device,

FIG. 2 a cross section through a prior art NLDMOS-SCR device,

FIG. 3 shows a top view of part of a prior art NLDMOS-array,

FIG. 4 shows a top view of part of one embodiment of an NLDMOS-array of the invention,

FIG. 5 shows a section through one embodiment of a an NLDMOS device of the invention,

FIG. 6 shows TLP drain current vs. drain-source TLP voltage curves one NLDMOS embodiment compared to a prior art NLDMOS,

FIG. 7 shows TLP drain current vs. drain-source TLP voltage curves for various NLDMOS device structures,

FIG. 8 shows a top view of part of another embodiment of an NLDMOS array of the invention,

FIG. 9 shows a three dimensional view of part of a prior art NLDMOS device, and

FIG. 10 shows a three dimensional view of the NLDMOS device of FIG. 9 with additional implants shown.

### DETAILED DESCRIPTION OF THE INVENTION

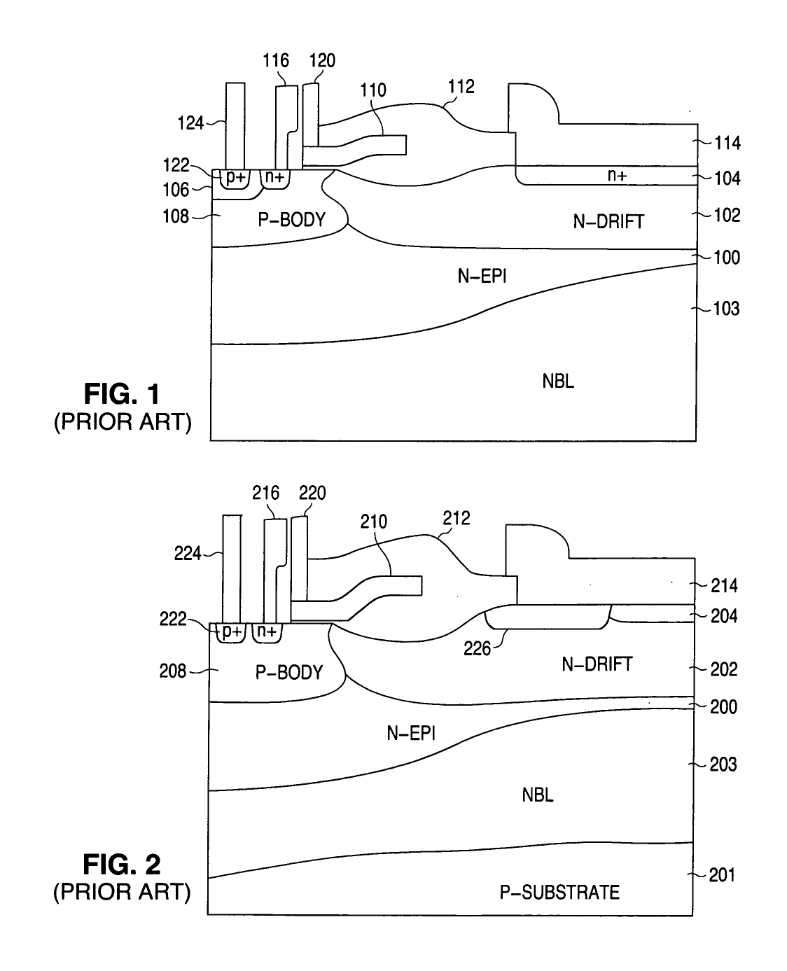

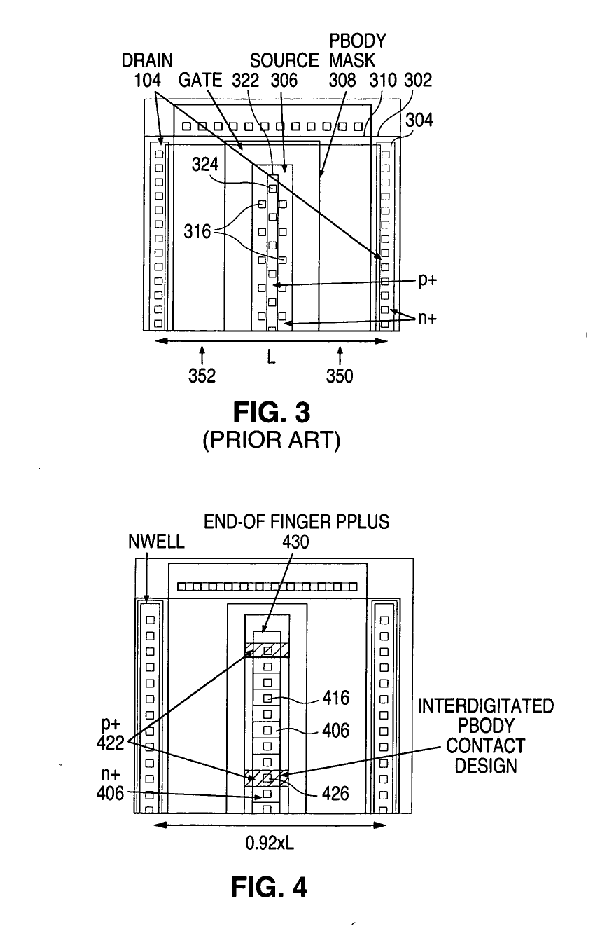

A prior art NLDMOS device was discussed above with respect to FIG. 1. Some of the features of the device can best be appreciated when viewed from the top as shown in the embodiment FIG. 3. FIG. 3 shows an n+ drain region 304 formed in the n-drift region 302. The poly gate 310 in this configuration is shown enclosing the n+ source 306, the p+ P body 322, and the P body 308 since two NLDMOS devices are arranged side by side with a common source region between them. As is evident from FIG. 3 the source contacts 316 are thus arranged in two parallel planes along the source finger 306. The right-hand portion of the source finger 306 serves as the source for a right-hand NLDMOS device 350, while the left-hand portion of the source 306 serves as the source for the left-hand NLDMOS device 352. The p+ P body 322 with its p+ contacts 324 is arranged in a plane between the left and right hand portions of the source 306.

In conventional NLDMOS design practice the p-body 308 is formed as part of a second diffusion using the poly gate 310 as a mask. Thus a cylindrical junction profile is formed between the poly gate 310 and the p-body 308.

The critical avalanche current is determined by the parasitic NPN defined by the n+ source, the p-body and the n+ drain with its extended n-drift region. The critical avalanche current could be adjusted without process changes i.e. using the same masks but different doping levels e.g. by increasing the p-body implant dose to reduce the internal base resistance of the parasitic NPN. However this would interfere with the operation of the NLDMOS since its internal base resistance is optimized for the particular operational regime.

The present invention therefore proposes a process change to meet or exceed the on-state resistance and other relevant figures of merit. For purposes of this application the gate length of the NLDMOS device is defined as the dimension in the direction between the drain and source contacts of the device. The gate width is the direction perpendicular to the gate length when viewed from the top of the device and thus extends in the direction of the source finger.

The present invention proposes one or more of the following changes to the drain contact region and source region design.

In one embodiment the p+ P body diffusions for contacting the P body are interdigitated between the n+ source regions as shown in FIG. 4, which shows the p+ P body diffusions interdigitated between n+ source regions 406, thereby aligning the p+ P body diffusions (together with their p+ P body contacts 426) with the source regions 406 (and their source contacts 416) in the same plane along the source finger. This has the effect of reducing the source region layout area by approximately 8% in the case of a 100 V NLDMOS device with 22.8 μm drain to drain contact spacing.

In another embodiment, which may be combined with the interdigitation discussed above, the n+ source material at the ends of the source fingers may be eliminated e.g. by implanting a p+ region at the end of each source finger as shown by the region 430 in FIG. 4. This improves the critical avalanche current but has the effect of reducing the n+ source finger length, which slightly increases R_{dson} because of the reduction in the source area thereby causing a slightly increased R_{dson} loss. However, as will be discussed below, the increased R_{dson} loss is compensated for by the reduced source region layout area achieved by the interdigitation of the p+ P body diffusions and the n+ source regions.

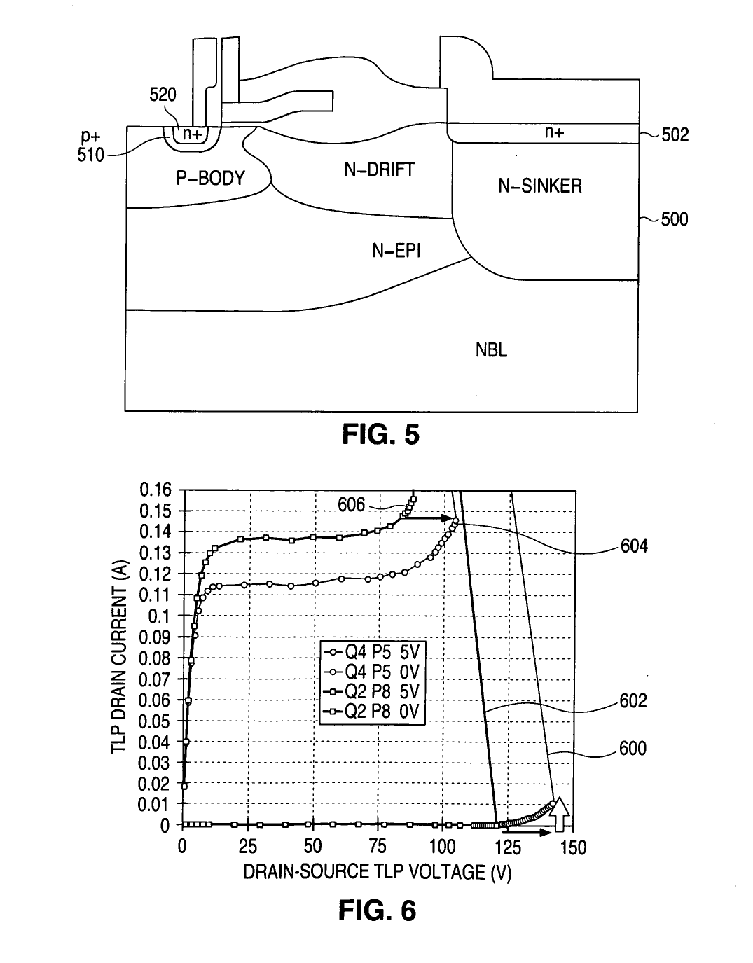

The above changes to the source region may be supplemented by the inclusion of an additional n-well or n-sinker implant 500 in the drain contact region as shown in the cross-sectional view of FIG. 5 to define an n-type region extending below the n+ drain region 502. The interdigitated p+ P body implants 510 are shown in the same longitudinal plane as the n+ source regions 520.

The effects of the above changes compared to the original prior art device for different gate biases are showing FIG. 6 which shows the transient line pulse (TLP) against the drain-source TLP voltage when including all of the above changes on the source and drain side as compared to the prior art device. At zero gate bias the critical avalanche current was increased by two orders of magnitude (curve curve 600 compared to prior art curve 602) and the snapback voltage was increased by between 15 and 20 V at both zero and 5 V gate bias. In particular curve 600 shows an increase to about 140 V compared to the 115 V of curve 602 for a gate bias of 0 V. Curve 604 shows an increase to about 105 V compared to the 85 V for the prior art curve 606 at a gate bias voltage of 5 V.

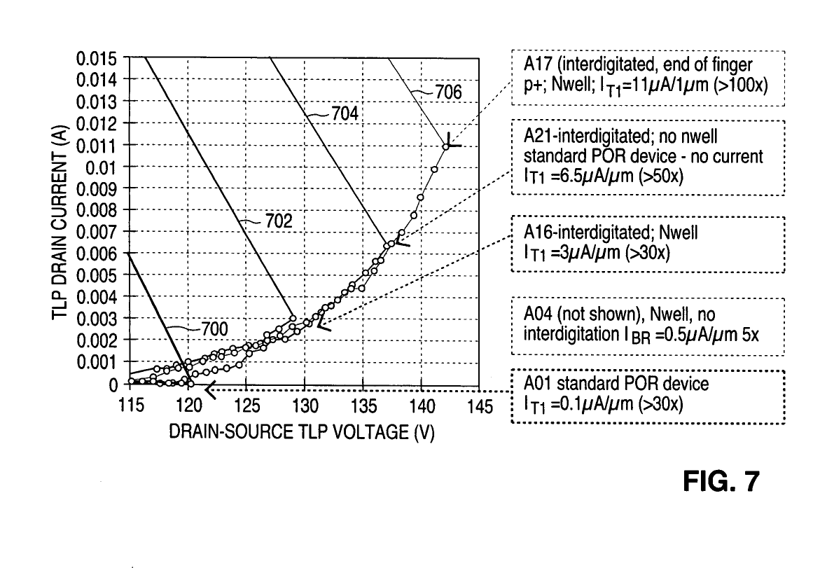

Different combinations of the above drain and source changes are also shown in the curves of FIG. 7 showing TLP drain current versus drain-source TLP voltage. Curve 700 shows a prior art NLDMOS device such as that shown in FIG. 1. This provides a critical avalanche breakdown current I_{T1}<0.1 μA/μm. Introducing only and n-well or n-sinker on the drain side without any changes to the source region design was found to produce a critical avalanche breakdown current I_{T1}=0.5 μA/μm (not shown in FIG. 7). Providing both interdigitation of the n+ source and p+ P body regions as well as n-well diffusion on the drain side provided I_{T1}=3 μA/μm (a 30× increase in the critical avalanche breakdown current) as shown by curve 702. Providing interdigitation plus p+ doping at the ends of the source fingers provided I_{T1}=6.5 μA/μm as shown by curve 704, while a combination of interdigitation, p+ doping at the ends of the source fingers, n-well diffusion on the drain side provided I_{T1}11 μA/μm as shown by curve 706.

Different amounts of interdigitation were analyzed and were found to have minimal impact on the drain-source on the resistance R_{dson}. For a minimum n+ source area where the p+ diffusions constitute 50% of the source region area, R_{dson} increased by only 2.6%, which is compensated for by a 7.9% improvement in R_{dson}. In a device with only a 1:9 ratio of p+/Pbody to n+ source area, the R_{dson} increase due to the reduced source area is only 1% with a total R_{dson} improvement of 7%.

Interdigitation of the source and Pbody alone was found not to provide any significant self protection capability advantage. N-well or n-sinker implant on the drain side alone was found to improve the critical avalanche current but required a significant increase in the drain length to avoid breakdown voltage reduction.

Further TCAD experiments with BCD NLDMOS (Bipolar CMOS DMOS N-laterally doped Metal Oxide Semiconductor), NLDMOS-SCR (NLDMOS-Silicon Controlled Rectifier) and two stage NLDMOS-SCR ESD (NLDMOS-SCR Electrostatic Discharge) devices showed that in spite of the increase in the critical avalanche current produced by p+ diffusions at the ends of the source fingers, such implants resulted in a reduction of the avalanche breakdown voltage V_{br} by some 10%.

On the other hand, the prior art device with n+ source regions at the ends of the source fingers also displayed poor breakdown voltage characteristics. The detrimental effect on breakdown voltage caused by an n+ source region at the end of a source finger, can be ascribed to a reduction in the doping level in the parasitic npn gate. The poly ring formed by the gate poly around the source finger defines corners at the ends of the finger, as shown in FIGS. 9 and 10, resulting in a spherical rather than cylindrical junction at the corners due to tilted implant shading. This reduces the parasitic base doping at the corners a indicated by the arrow 1004, resulting in reduced breakdown voltage.

It was found that a cell with an NLDMOS layout e.g. NLDMOS, BCD NLDMOS, NLDMOS-SCR that was provided with a P body diffusion at the ends of the source fingers to eliminate both the p+ Pbody diffusion as well as the prior art n+ source at the ends of the fingers provided not only for higher breakdown voltage but had the benefit of still retaining the advantage of increased avalanche current.

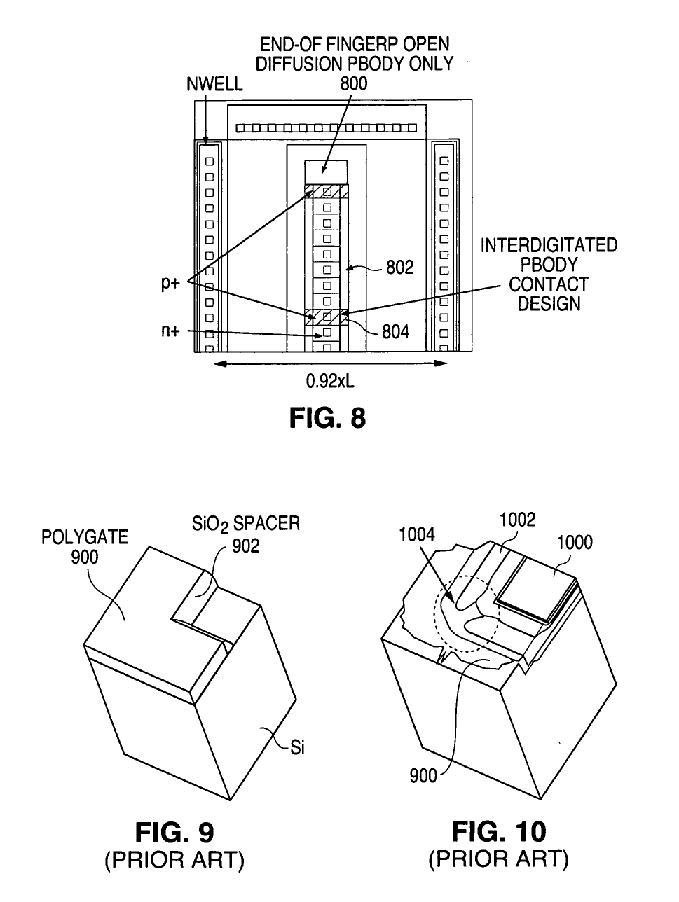

One such embodiment is shown in FIG. 8 which shows the P body diffusion 800 at the end of the source finger 802. The diffusion 800 can be combined with interdigitated p regions 804 and drain-side n-well implants. For purposes of this application the term NLDMOS includes any NLDMOS structures, including BCD NLDMOS, NLDMOS-SCR and two stage NLDMOS-SCR ESD devices. Thus, replacing the n+ source diffusion 1000 (FIG. 10) with a P body diffusion as proposed by the diffusion 800 in FIG. 8 was found to avoid a reduced breakdown voltage.

While the idea of an n-well implant on the drain side is not new, the introduction of diffusions at the ends of the source fingers and interdigitation of n+ source and p+ P body regions is new, as is the combination of such interdigitation and source finger diffusions with n-well or n-sinker diffusions on the drain side.

What is claimed is:

1. An NLDMOS device that includes,
an n+ drain region,
at least one n+ source region defining a source finger with a longitudinal axis, and
a P body with at least one p+ P body diffusion region, wherein the end of the source finger is defined by a P body diffusion.

2. An NLDMOS device of claim 1, wherein the at least one p+ P body diffusion region is arranged substantially along the longitudinal axis of the source finger to define a source finger with at least one interdigitated p+ P body diffusion region.

3. An NLDMOS device of claim 1, wherein a p+ P body diffusion region is included at the end of the source finger.

4. An NLDMOS device of claim 1, further including an n-well or n-sinker region extending underneath the n+ drain region.

5. An NLDMOS device of claim 2, further including an n-well or n-sinker region extending underneath the n+ drain region.

6. A method of increasing the critical avalanche current of an NLDMOS device that includes an n+ drain region, at least one n+ source region defining a source finger, and a P body with at least one p+ P body diffusion region, the method comprising
providing at least one of, a p-type end region to the source finger, and an interdigitated p+ P body implant into the source finger.

7. A method of claim 6, wherein the p-type end region comprises a P body implant or a p+ P body implant.

8. A method of claim 6, further comprising providing a drain side n-well or n-sinker implant.

9. An NLDMOS array comprising multiple NLDMOS devices, each device including an n+ drain region, at least one n+ source region forming a source finger that defines a longitudinal axis, and a P body with at least one p+ P body diffusion region, wherein the source fingers define an end formed by a P body implant or a p+ P body implant.

10. An NLDMOS array of claim 9, wherein adjacent NLDMOS devices in the array share a source finger.

11. An NLDMOS array 9, wherein the source fingers each have one or more interdigitated p+ P body diffusions wherein the p+ P body diffusions lie substantially along the longitudinal axes of the source fingers.

12. An NLDMOS array 10, wherein the source fingers each have one or more interdigitated p+ P body diffusions wherein the p+ P body diffusions lie substantially along the longitudinal axes of the source fingers.
